(19) United States
(12) Patent Application Publication
(10) Pub. No.: US 2013/0194657 A1
(43) Pub. Date: Aug. 1, 2013

(54) OPTICAL AMPLIFIER AND MANUFACTURING METHOD OF OPTICAL AMPLIFIER

(71) Applicant: FUJITSU OPTICAL COMPONENTS LIMITED, Kawasaki (JP)

(72) Inventor: Tetsuo ISHIZAKA, Inagi (JP)

(73) Assignee: FUJITSU OPTICAL COMPONENTS LIMITED, Kawasaki (JP)

(21) Appl. No.: 13/670,929

(22) Filed: Nov. 7, 2012

(30) Foreign Application Priority Data
Jan. 31, 2012 (JP) 2012-019299

(51) Int. Cl. H01S 5/20; H01L 33/08

(52) U.S. Cl. 359/344; 438/31; 257/E33.067

(57) ABSTRACT

An optical amplifier includes multiple semiconductor optical amplifiers (SOAs) provided on a semiconductor substrate and having different wavelength bands to be amplified; multiple branching paths that branch an input optical signal and input the branched optical signals into the parallel SOAs, respectively; and multiple combining paths that combine and output the optical signals after amplification by the SOAs.

### CROSS REFERENCE TO RELATED APPLICATIONS

This application is based upon and claims the benefit of priority of the prior Japanese Patent Application No. 2012-019299, filed on Jan. 31, 2012, the entire contents of which are incorporated herein by reference.

### FIELD

The embodiments discussed herein are related to an optical amplifier that amplifies an optical signal and a manufacturing method of the optical amplifier.

### BACKGROUND

Recently, optical amplifiers are used as optical transmission modules for long-haul transmission of optical signal. Fiber amplifiers such as the erbium-doped optical fiber amplifier (EDFA) are used as the optical amplifiers. Small optical amplifiers such as the semiconductor optical amplifier (SOA) are also available as a commercial product recently.

In WDM optical communication, transmission characteristics vary for each wavelength since the wavelengths are amplified differently. Thus, the level of input light is adjusted for each wavelength or optical amplifiers are connected in series (i.e., cascade connection) to broaden the wavelength band to be transmitted (see, for example, Japanese Laid-open Patent Publication Nos. 2006-53343 and 2002-330106).

Optical modules for long-haul transmission require optical amplifiers as described above. Conventionally, however, the overall size of the optical module cannot be reduced. An optical fiber amplifier requires a long optical fiber and a pump-light source, resulting in an increased number of elements. In particular for wider bandwidth, the optical fiber amplifier cannot be made smaller since the amplifier requires pump-light sources of different wavelengths.

On the other hand, the SOA has a narrow wavelength band that can be amplified for optical communication, and the wavelength characteristics varies (i.e. tilt) according to a change in the gain. Thus, specification of optical elements has to be strict if the SOA is used as the optical module, thereby preventing mass production and cost reduction. Further, the optical amplifiers connected in series (i.e., cascade connection) cannot broaden the band.

### SUMMARY

According to an aspect of an embodiment, an optical amplifier includes multiple semiconductor optical amplifiers (SOAs) provided on a semiconductor substrate and having different wavelength bands to be amplified; multiple branching paths that branch an input optical signal and input the branched optical signals into the parallel SOAs, respectively; and multiple combining paths that combine and output the optical signals after amplification by the SOAs.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a diagram of a configuration of an optical amplifier according to a first embodiment;

FIG. 1B is a diagram of a configuration of a branching unit;

FIG. 2 is a chart of the characteristics of a combined signal resulting from combining signals output from SOAs;

FIG. 3 is a chart of the output characteristics of an SOA according to a change in gain;

FIG. 4 is a chart of the characteristics of the combined signal according to a change in the gain;

FIG. 5 is a diagram of a configuration of an optical amplifier according to a second embodiment;

FIG. 6 is a diagram of a connection structure for a monitor;

FIG. 7 is a flowchart of a gain control of the SOAs according to the second embodiment;

FIG. 8 is a diagram of a configuration of an optical amplifier according to a third embodiment;

FIG. 9 is a diagram of a configuration of an optical amplifier according to a fourth embodiment;

FIG. 10 is a flowchart of a phase control of outputs from the SOAs according to the fourth embodiment;

FIG. 11A is a cross section depicting a step of manufacturing the optical amplifier (part 1);

FIG. 11B is a cross section depicting a step of manufacturing the optical amplifier (part 2);

FIG. 11C is a cross section depicting a step of manufacturing the optical amplifier (part 3);

FIG. 12A is a cross section depicting a step of forming SOAs of different wavelength characteristics on a semiconductor substrate (part 1); and

FIG. 12B is a cross section depicting a step of forming SOAs of different wavelength characteristics on a semiconductor substrate (part 2).

### DESCRIPTION OF EMBODIMENTS

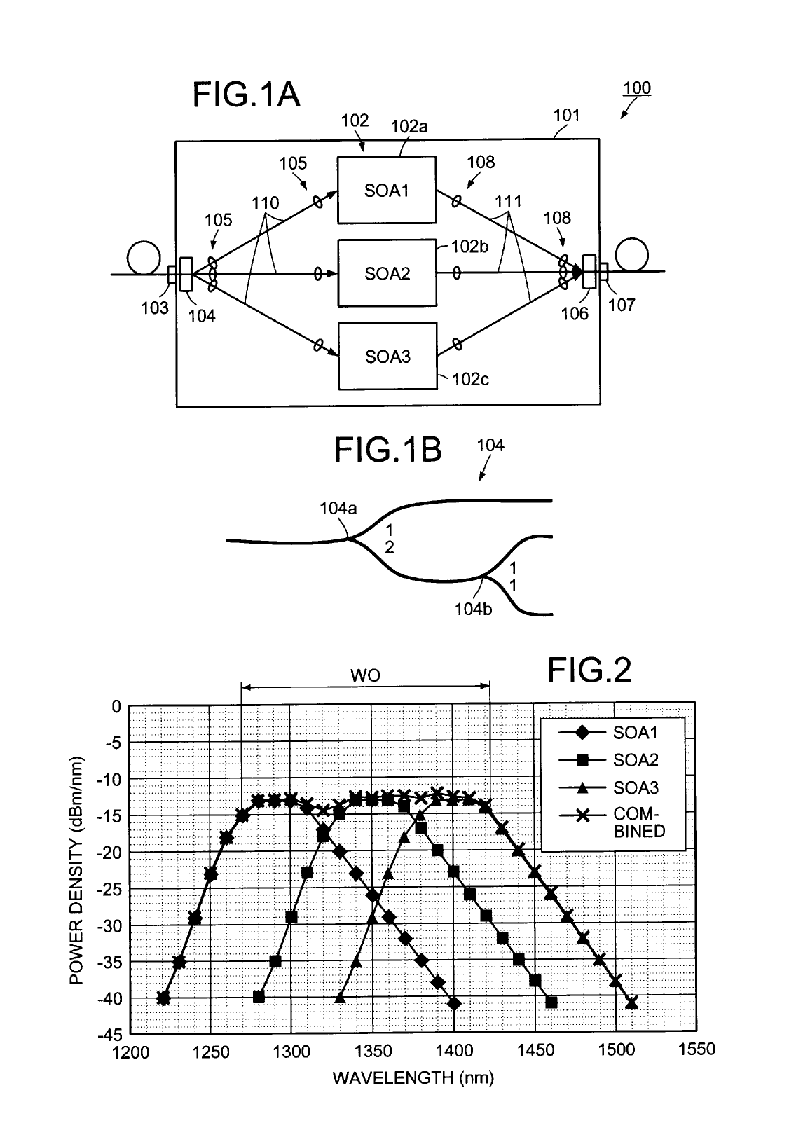

Preferred embodiments of a technology disclosed herein will be explained with reference to the accompanying drawings. FIG. 1A is a diagram of a configuration of an optical amplifier according to a first embodiment. An optical amplifier 100 includes a semiconductor substrate 101 and semiconductor optical amplifiers (SOAs) 102 (102a to 102c) formed on the semiconductor substrate 101.

The SOAs 102 of different wavelength characteristics are arranged in parallel on the semiconductor substrate 101. Thus, a branching unit 104 such as an optical coupler is provided downstream of an input unit 103 on the semiconductor substrate 101, and branches an optical signal input from an optical fiber, etc. The same optical signal branched at the branching unit 104 is input into the SOAs 102 (102a to 102c) via branching paths 110.

The branching paths 110 are transmission paths in the air formed by lenses 105 provided at the output of the branching unit 104 and the input of each of the SOAs 102 (102a to 102c). Thus, the optical signals branched at the branching unit 104 are input into the SOAs 102 (102a to 102c), respectively.

The SOAs 102 (102a to 102c) have gain characteristics for given ranges having given center wavelengths that differ respectively. Although three SOAs 102 (102a to 102c) are provided in FIG. 1A, the number of the SOAs 102 may be changed according to a required bandwidth. Each of the SOAs 102 (102a to 102c) can be made small (for example, 2 mm square).

The optical signals amplified by the SOAs 102 (102a to 102c) are input into a combining unit 106 via combining paths 111, combined by the combining unit 106, and output from an output unit 107 to an optical fiber, etc.

The combining paths 111 are transmission paths in the air formed by lenses 108 provided at the output of each of the SOAs 102 (102a to 102c) and the input of the combining unit 106. Thus, the optical signals output from the SOAs 102 (102a to 102c) are input into the combining unit 106.

The branching paths 110 between the branching unit 104 and the SOAs 102 depicted in FIG. 1A and the combining paths 111 between the SOAs 102 and the combining unit 106 transmit the optical signals in the air by the lenses 105 and 108, respectively. Alternatively, optical fibers or optical waveguides described later can be used as the branching paths 110 and the combining paths 111.

FIG. 1B is a diagram of a configuration of the branching unit. A multi-mode interference (MMI) or a branch coupler can be used as the branching unit 104 that branches one input into three by two branches included therein at each of which one input is branched into two. At the upstream branch 104a, the input optical signal is branched and output at a ratio of 1:2. Two-thirds of the input optical signal is further branched and output at a ratio of 1:1 at the downstream branch 104b. Thus, the branching unit 104 divides the input optical signal into three equal signals, and outputs the signals.

The optical signal can be branched into a greater number of signals by increasing the number of the branches 104a. The combining unit 106 combines the signals by a configuration that is similar to the branching unit 104 depicted in FIG. 1B but in which the input and the output are interchanged.

FIG. 2 is a chart of the characteristics of a combined signal of the signals output from the SOAs. The horizontal axis represents wavelength, and the vertical axis represents the power density (optical output). Three SOAs 102a to 102c have different center wavelengths of gain in FIG. 2. For example, the center wavelength of SOA 1 (102a) is 1290 nm, the center wavelength of SOA 2 (102b) is 1350 nm, and the center wavelength of SOA 3 (102c) is 1400 nm.

Thus, flat wavelength characteristics having a given bandwidth can be achieved. Each of the characteristics of SOA 1 (102a) to SOA 3 (102c) attenuates by a given gain (for example, 1 dB or 3 dB) on the shorter-wavelength side and the longer-wavelength side. Thus, wavelength bands to be amplified by the SOAs 102 are arranged such that an end (shorter-wavelength side) of the wavelength band of one SOA 102b where the characteristics attenuate by the given gain overlaps with an end (longer-wavelength side) of the wavelength band of another SOA 102a. Similarly, the other end (longer-wavelength side) of the wavelength band of the SOA 102b where the characteristics attenuate by the given gain overlaps with an end (shorter-wavelength side) of the wavelength band of another SOA 102c. Thus, a given bandwidth WO where the characteristics are flat over a broad bandwidth can be secured by merely combining the signals output from SOA 1 (102a) to SOA 3 (102c).

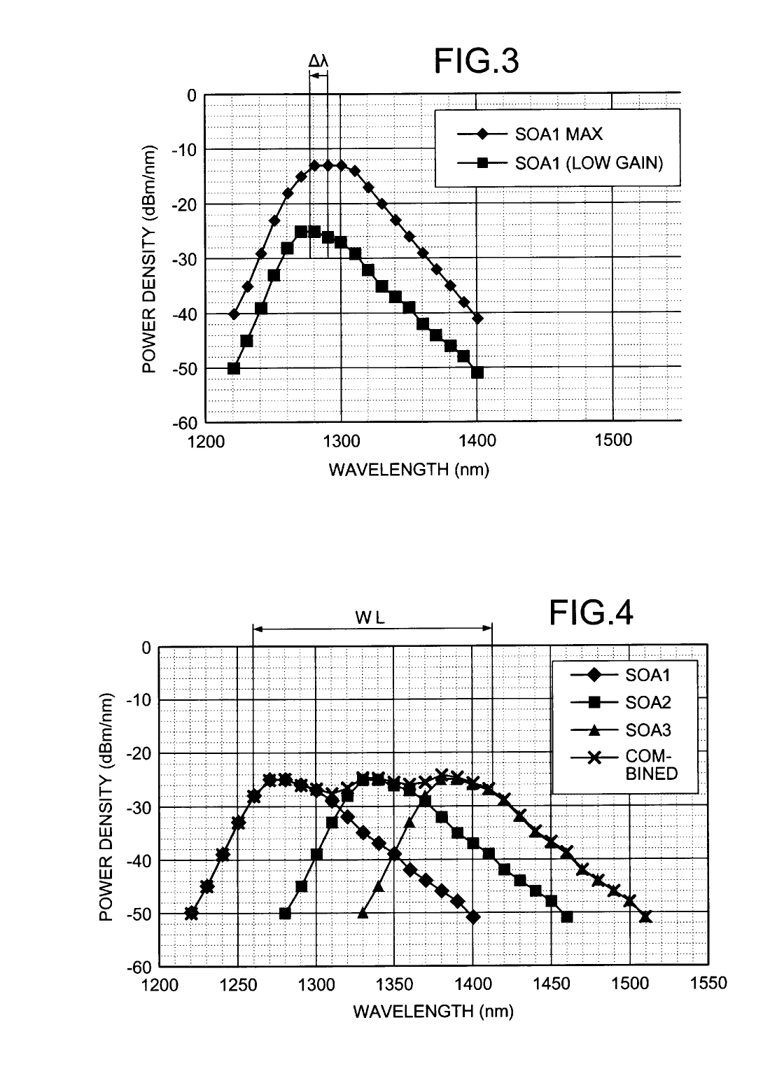

FIG. 3 is a chart of the output characteristics of the SOA according to a change in the gain. As depicted, a shift (tilt) occurs in the center wavelength of the SOA according to a change in the gain. FIG. 3 depicts an example when the gain is low, and an example when the gain is the maximum. In the former example, the center wavelength shifts (tilts) toward the shorter-wavelength side by the wavelength Δλ.

FIG. 4 is a chart of the characteristics of the combined signal according to a change in the gain. As depicted in FIG. 3, the center wavelength of the SOA 102 changes according to a change in the gain. Similarly, as depicted in FIG. 4, the center wavelength changes according to a change in the gain for the combination of the SOAs 102 (102a to 102c) depicted in FIG. 2.

In FIG. 4, compared to FIG. 2, the center wavelength of each SOA 102 shifts toward the shorter-wavelength side when the gain is low. Conversely, the center wavelength of each SOA 102 shifts toward the longer-wavelength side when the gain is increased.

If the direction of the tilt according to a change in the gain is preliminary known as described above, the center wavelengths of the SOAs 102 (102a to 102c) are set such that the characteristics of the combined signal of the signals output from the SOAs 102 (102a to 102c) after the change in the gain become flat as depicted in FIG. 4.

The center wavelengths are selected such that a flat characteristic of the combined signal can be achieved even when the center wavelengths have changed after the change in the gain. Thus, a flat and broad (with the bandwidth WL when the gain is low) characteristics of the combined signal can be achieved even after a change in the gain and the center wavelength of any of the SOAs 102 (102a to 102c). In other words, the variable gain and the wavelength band to be amplified that changes according to a change in the gain are set (operated) within a given range based on the tilt of the center wavelength according to a change in the gain.

According to the first embodiment, SOAs having different center wavelengths are arranged in parallel and amplify the branched optical signals, respectively, thereby amplifying optical signals over a wider band as the number of the SOAs provided in parallel increases. Further, the SOA itself is small and has a compact size even when arranged in parallel on the substrate, thereby reducing the overall size of the optical module.

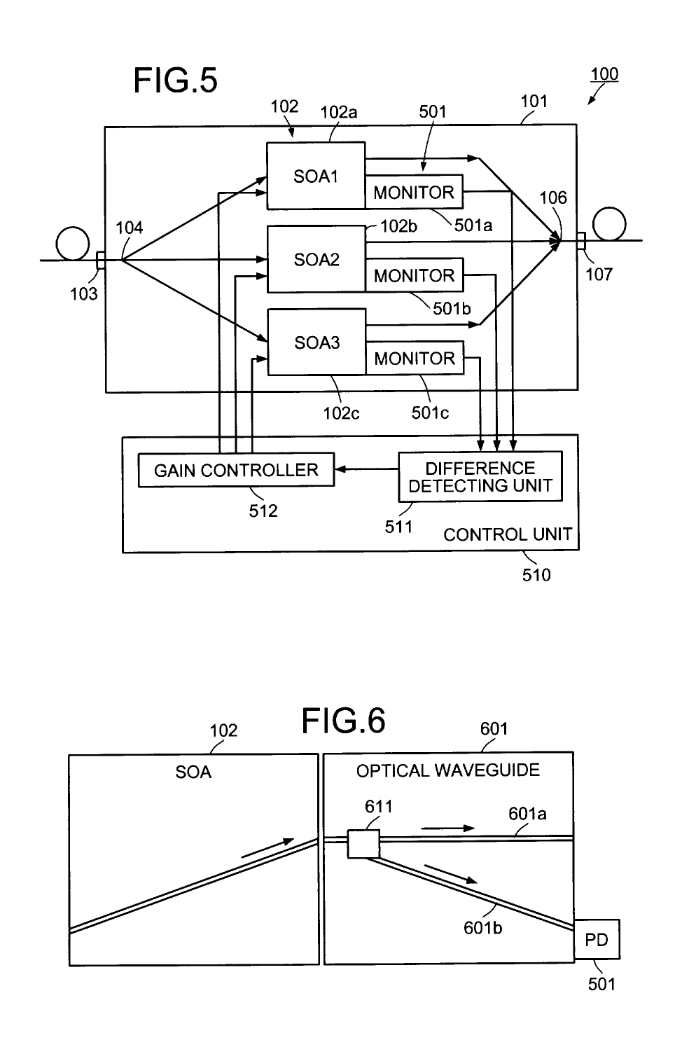

FIG. 5 is a diagram of a configuration of an optical amplifier according to a second embodiment. The configuration is basically the same as that of the first embodiment (FIG. 1A), and thus the branching unit 104, the combining unit 106, and the lenses 105 and 108 are omitted in FIG. 5. The output levels of the SOAs 102 (102a to 102c) are detected by monitors 501 (501a to 501c) such as PDs.

The outputs detected by the monitors 501 (501a to 501c) are input into a control unit 510 that adjusts the gain of each of the SOAs 102 (102a to 102c) separately based on the outputs detected by the monitors, thereby achieving the flat characteristics of the combined signal.

The control unit 510 includes a difference detecting unit 511 that detects a change in the output detected by each of the monitors 501 (501a to 501c), that is, the difference from the previously-detected output, and a gain controller 512 that adjusts the gain of each SOA 102 separately based on the difference detected by the difference detecting unit 511.

The band that can be detected by each monitor 501 is broader than the band of the SOA 102 depicted in FIG. 3. For example, the band of a PD used as the monitor 501 is about 400 nm. Thus, the monitors 501 (501a to 501c) can sufficiently detect the outputs within the bands of the SOAs 102 (102a to 102c), respectively.

FIG. 6 is a diagram of a connection structure for the monitor. The SOA 102 and the subsequent portion are depicted. The optical signal output from the SOA 102 is input into an optical waveguide 601 in which the optical signal is branched into two by a branching unit 611 such as an optical coupler. One optical signal is lead to the output unit 107 depicted in FIG. 1A via an optical waveguide 601a. The other optical signal is lead to the monitor (PD) 501 via an optical waveguide 601b, and the output from the SOA 102 is detected by the monitor 501 as a monitor value.

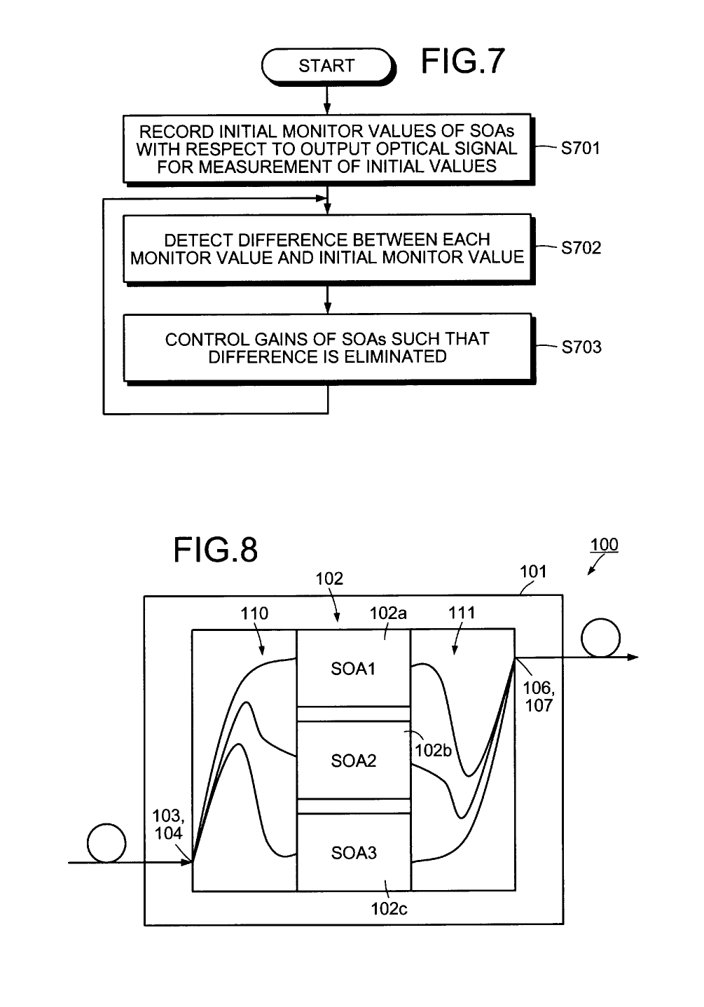

FIG. 7 is a flowchart of a gain control of the SOAs according to the second embodiment. The optical output from the optical amplifier 100 decreases due to a fluctuation in the input level and/or degradation over time of the SOAs 102, etc.; however, the following control stabilizes the output of the optical signal.

The control unit 510 sets initial values of the optical amplifier 100 (step S701). In the setting, the monitor values of the SOAs 102 (102a to 102c) with respect to the output signal are detected by the monitors 501 (501a to 501c) and recorded. Here, the values detected for the optical signals after amplification by the SOAs 102 (102a to 102c) are stored as initial monitor values into a storing unit such as a memory (not depicted) in the control unit 510.

Subsequent processes are repeated regularly (at a given timing, etc.) during operation. The difference detecting unit 511 detects the difference of each monitor value from the initial monitor value (step S702).

Specifically, the difference detecting unit 511 reads the initial monitor values of the SOAs 102 (102a to 102c) from the storing unit, and detects the differences between the initial monitor values and the monitor values actually detected by the monitors 501 (501a to 501c).

The gain controller 512 controls the gain of any of the SOAs 102 (102a to 102c) for which the difference is detected such that the difference is eliminated (gain control) (step S703).

For example, if the monitor value of the SOA 102a actually detected at step S702 is lower than the initial monitor value, the gain controller 512 increases the gain of the SOA 102a. This feedback control repeated regularly stabilizes the outputs from the SOAs 102 (102a to 102c) even when the input level fluctuates and/or the optical elements such as the SOAs 102 have degraded over time.

According to the second embodiment, the monitors enable an adjustment of signals input into the SOAs, respectively, and a control of the power of signals output from the SOAs. The outputs from the SOAs can be stabilized even when the input level fluctuates and/or the optical elements such as the SOAs have degraded over time. Further, a given, wide bandwidth can be secured for the characteristics of the combined signal of the signals output from the SOAs.

Not limited to the stabilization, the optical amplifier 100 according to the second embodiment can achieve any output optical power by intentionally increasing/decreasing the total optical output (gain) of the combined signal of the signals output from the SOAs.

FIG. 8 is a diagram of a configuration of an optical amplifier according to a third embodiment. In the third embodiment, the SOAs 102 (102a to 102c) are arranged on the semiconductor substrate 101 to form an array. Although the monitors 501 and the control unit 510 described in the second embodiment (FIG. 5) are omitted, the gains of the SOAs 102 (102a to 102c) are controlled by the monitors 501 and the control unit 510.

In the third embodiment, the branching paths 110 from the branching unit 104 to the SOAs 102 (102a to 102c) have the same length (optical path length). Similarly, the combining paths 111 from the SOAs 102 (102a to 102c) to the combining unit 106 have the same length (optical path length). In the third embodiment, optical waveguides of the same length formed on the semiconductor substrate 101 are used as the branching paths 110 and the combining paths 111. Alternatively, optical fibers of the same length may be used as the branching paths 110 and the combining paths 111.

As to the input unit 103, for example, an optical fiber is directly coupled to the branching unit 104 to reduce the optical loss. As to the output unit 107, an optical fiber is directly coupled to the combining unit 106.

According to the third embodiment, the branching paths 110 and the combining paths 111 have curved portions and differing shapes, respectively. However, the branching paths 110 from the branching unit 104 to the SOAs 102 (102a to 102c) have the same optical path length, and the combining paths 111 from the SOAs 102 (102a to 102c) to the combining unit 106 have the same optical path length.

According to the third embodiment, the branching paths 110 having the same optical path length and the combining paths 111 having the same optical path length can reduce the interference of optical signals between the paths and achieve the same signal characteristics (signal degradation characteristics) for all paths, thereby maintaining the flat output.

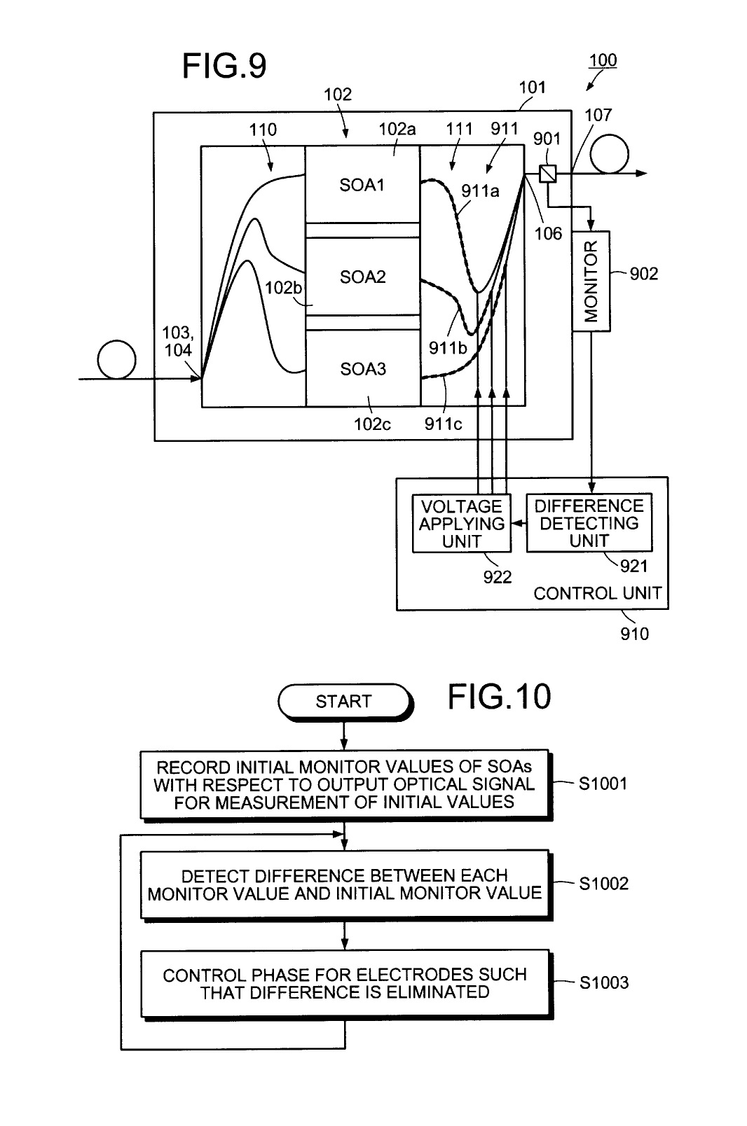

FIG. 9 is a diagram of a configuration of an optical amplifier according to a fourth embodiment. In the fourth embodiment, similar to the third embodiment, the branching paths 110 from the branching unit 104 to the SOAs 102 (102a to 102c) have the same length. Similarly, the combining paths 111 from the SOAs 102 (102a to 102c) to the combining unit 106 have the same length.

In the fourth embodiment, control electrodes 911 (911a to 911c) having a given length are provided on and along the combining paths 111 from the SOAs 102 (102a to 102c) to the combining unit 106, respectively. In the figure, the control electrodes 911a to 911c have the same length and are provided on the combining paths 111. Similar to the third embodiment, the branching paths 110 and the combining paths 111 are formed by optical waveguides on which the control electrodes 911 for changing/controlling the phase of the optical signals are provided.

The control electrodes 911 (911a to 911c) change the voltages to be applied, thereby changing the phase of the optical signals transmitted through the optical waveguides as the branching paths 110 and the combining paths 111, changing the refraction index, and changing the optical path length as a result. The branching paths 110 and the combining paths 111 have the same length, respectively; however, the lengths may be different due to a variation in the manufacturing process, etc. Thus, the control electrodes 911 (911a to 911c) are provided to equalize the lengths of the branching paths 110 and the combining paths 111, thereby reducing the interference between the optical signals amplified by the SOAs 102 (102a to 102c).

For this control, a branching unit 901 is provided downstream of the combining unit 106 to branch the combined optical signal. One of the branched optical signal is output from the output unit 107, and the other is input into a monitor 902 that is a waveform monitor (spectrum analyzer) that monitors the waveforms output from the SOAs 102 (102a to 102c) and detects the height (optical level) of each waveform.

The waveforms detected by the waveform monitor are input into a control unit 910 that includes a difference detecting unit 921 and a voltage applying unit 922. The difference detecting unit 921 detects a change in the height of the waveform output from each of the SOAs 102 (102a to 102c), that is, the difference from the previously-detected height. The voltage applying unit 922 separately adjusts the voltages applied to the control electrodes 911 (911a to 911c) corresponding to the SOAs 102 (102a to 102c) separately based on the difference detected by the difference detecting unit 921.

FIG. 10 is a flowchart of a phase control of the outputs from the SOAs according to the fourth embodiment. The optical output from the optical amplifier 100 decreases due to a fluctuation in the input level and/or degradation over time of the SOAs 102, etc.; however, the following control stabilizes the output of the optical signal.

The control unit 910 sets initial values of the optical amplifier 100 (step S1001). In the setting, monitor values of the SOAs 102 (102a to 102c) with respect to the output signal are detected by the monitor 902 and recorded. Here, for the optical signals that have been amplified by the SOAs 102 (102a to 102c) and combined, the waveforms output from the SOAs 102 (102a to 102c) (for example, the height of the waveform for each wavelength) are stored as initial monitor values into a storing unit such as a memory (not depicted) in the control unit 910.

Subsequent processes are repeated regularly (at a given timing, etc.) during operation. The difference detecting unit 921 detects the difference of each monitor value from the initial monitor value (step S1002). Specifically, the difference detecting unit 921 reads the initial monitor values for the height of the waveform in the wavelength band of each of the SOAs 102 (102a to 102c) from the storing unit, and detects the differences between the initial monitor values and the monitor values (heights of the waveforms) in the wavelength bands actually detected by the monitor 902.

The voltage applying unit 922 changes the voltage to be applied to any of the control electrodes 911 (911a to 911c) corresponding to a range of wavelengths for which the difference is detected such that the difference is eliminated (phase control) (step S1003).

For example, if the monitor value (the height of the waveform) of the SOA 102a actually detected at step S1002 is lower than the initial monitor value, the voltage applying unit 922 changes (increases or decreases) the voltage applied to the control electrode 911a provided on the combining path 111 at the output of the SOA 102a, thereby changing (increasing or decreasing) the refraction index of the optical waveguide forming the combining path 111 at the output of the SOA 102a. As a result, the optical path length is changed and the output from the SOA (the height of the waveform) 102a becomes the initial value. Further, the interference from the other adjacent optical waveguides can be reduced.

This feedback control repeated regularly stabilizes the outputs from the SOAs 102 (102a to 102c) even when the input level fluctuates and/or the optical elements such as the SOAs 102 have degraded over time.

According to the fourth embodiment, the monitor monitors the waveforms, thereby detecting a change in the height of a waveform due to a change in the phase, and controlling the power of the signal output from each of the SOAs. In particular, differing optical path lengths of the combining paths 111 due to variation (that occurs even though the combining paths 111 are precisely formed as optical waveguides) are equalized by changing the phase, thereby making the output of the combined signal constant without interference from the other optical signals. Thus, a given, wide bandwidth can be secured for the characteristics of the combined signal of the signals output from the SOAs.

In the above description, the control electrodes 911 (911a to 911c) having a given length are provided on and along the combining paths 111 from the SOAs 102 (102a to 102c) to the combining unit 106. In addition, control electrodes having a given length may be provided on and along the branching paths 110 from the branching unit 104 to the SOAs 102 (102a to 102c). Thus, not only the optical path lengths of the combining paths 111, but also the optical path lengths of the branching paths 110 are equalized, thereby equalizing the total optical path lengths of the branching paths 110 and the combining paths 111.

In the fourth embodiment, the gain control described in the second embodiment may be also employed. Specifically, the control unit 910 includes the components depicted in FIG. 5, stabilizes the output power by the gain control of the SOAs, and reduces the interference between the optical waveguides by the phase control for the combining paths 111.

A manufacturing method of the optical amplifier is described next. Different from optical fiber amplifiers, the optical amplifier using the SOAs 102 can be manufactured by a semiconductor process. The SOAs 102 (102a to 102c) may be manufactured as an array as described in the third embodiment.

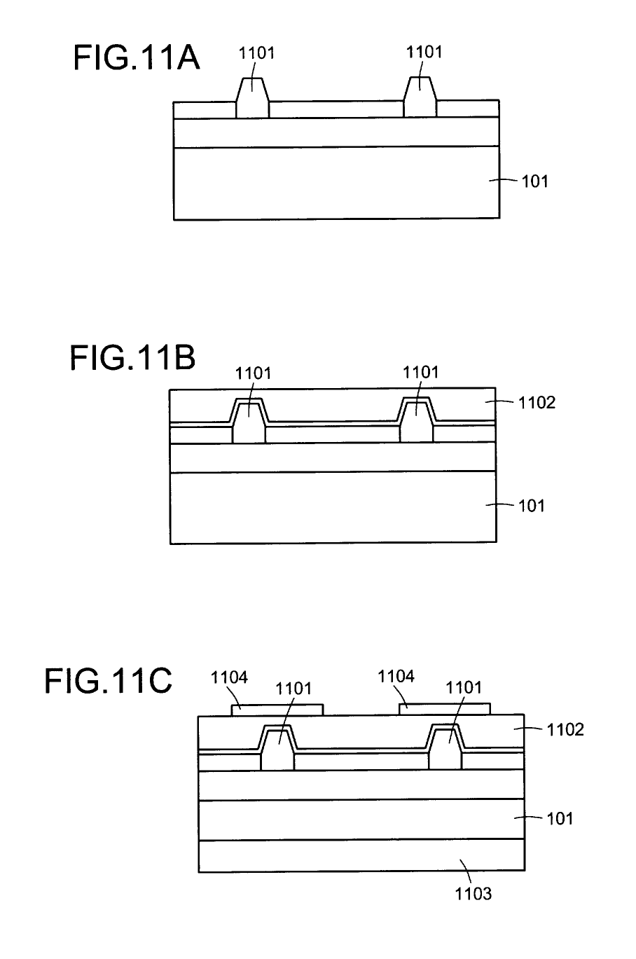

FIGS. 11A to 11C are cross sections depicting steps of manufacturing the optical amplifier, respectively. As depicted in FIG. 11A, source gas is provided on the semiconductor substrate 101 such as GaAs using metal organic chemical vapor deposition (MOCVD) method. A multi-layered semiconductor thin film is formed on the heated semiconductor substrate 101 by thermolysis reaction, and ridges 1101 that becomes the optical waveguides for transmitting the optical signals are formed. The ridges 1101 become not only the optical waveguides functioning as the branching paths 110 and the combining paths 111 described above, but also the SOAs 102 (102a to 102c).

As depicted in FIG. 11B, material gas of different material and having a different transmittance, for example, is provided on the ridges 1101 formed by the multi-layered semiconductor thin film, and a multi-layered semiconductor thin film 1102 is formed using MOCVD method. Thus, the optical waveguides that confine the lights within the ridges 1101 and transmit the optical signals can be formed.

As depicted in FIG. 11C, for optical amplification, an n electrode 1103 and p electrodes 1104 are formed in the area on the semiconductor substrate 101 where the SOAs 102 are provided. The p electrodes 1104 are formed above the ridges 1101 corresponding to the SOAs 102 (102a to 102c), respectively.

In the embodiments described above, the SOAs 102 (102a to 102c) have different wavelength characteristics, respectively. A method of forming the SOAs 102 (102a to 102c) of different wavelength characteristics on one semiconductor substrate 101 is described next.

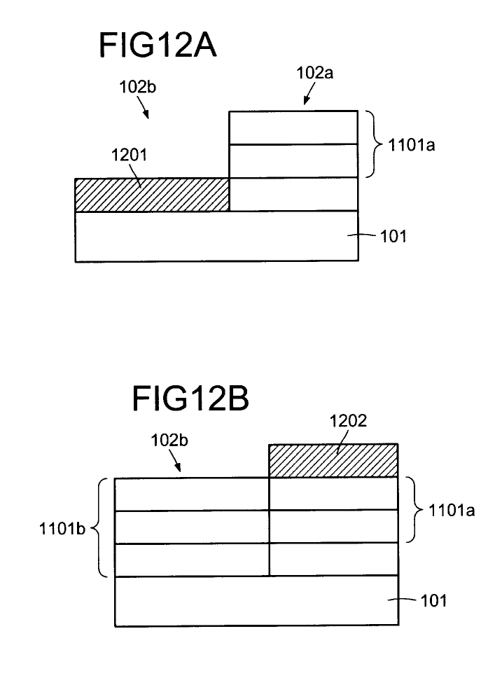

FIGS. 12A and 12B are cross sections depicting steps of forming SOAs of different wavelength characteristics on a semiconductor substrate. Two SOAs 102a and 102b of different wavelength characteristics are formed in the following example.

FIG. 12A is a diagram of a state after one SOA 102a is formed using MOCVD method depicted in FIG. 11A. Material gas corresponding to the wavelength characteristics of the SOA 102a is provided. A multi-layered semiconductor thin film is formed on the heated semiconductor substrate 101 by thermolysis reaction, and the ridge 1101a that becomes the optical waveguide is formed. Here, a mask 1201 is provided on the area of the semiconductor substrate 101 where the other SOA 102b is to be formed, such that the SOA 102b is not formed yet.

A mask 1202 is provided on the SOA 102a, and material gas corresponding to the wavelength characteristics of the other SOA 102b is provided. A multi-layered semiconductor thin film is formed on the heated semiconductor substrate 101 by thermolysis reaction, and the ridge 1101b that becomes the optical waveguide is formed.

Thus, two SOAs 102a and 102b having differing wavelength characteristics for optical amplification are formed on the same semiconductor substrate 101. In the above description, a method of forming two SOAs 102 (102a and 102b) is described; however, the SOAs 102 (102a to 102c) of different wavelength characteristics for optical amplification can be formed by masking areas for SOAs other than the SOA to be formed and providing different material gas.

According to the manufacturing method described above, optical waveguides functioning as the branching paths 110 and the combining paths 111 provided upstream and downstream of the SOA 102, respectively, can be monolithically fabricated by semiconductor process, taking into account the optical path length on the semiconductor substrate 101. Thus, the branching paths 110 and the combining paths 111 having optical path lengths as designed can be manufactured with high accuracy, thereby reducing the interference between the optical signals amplified by the SOAs 102 (102a to 102c).

Further, the SOAs 102 can be easily manufactured by merely adding a step of forming the SOAs 102 in the SOA areas at the same time as forming the optical waveguides on the semiconductor substrate 101 as the branching paths 110 and the combining paths 111. Furthermore, the branching unit 104 and the combining unit 106 depicted in FIG. 1B and the branching unit 611 depicted in FIG. 6 can be formed simultaneously at the step of forming the optical waveguides.

The optical amplifier 100 described above can reduce fluctuation in the phase due to temperature by a temperature control performed by a thermoelectric cooler (TEC) such as a TEC using a Peltier element. The TEC is provided on the back of the semiconductor substrate 101, for example, and detects the temperature of the semiconductor substrate 101 and heats/cools the semiconductor substrate 101, thereby keeping the temperature of the semiconductor substrate 101 constant.

According to the embodiments described above, the SOAs are formed on the semiconductor substrate as the optical amplifiers and thus, optical amplifiers occupy only space of the semiconductor substrate, thereby reducing the size of the optical module to which the optical amplifiers are applied. Further, an optical signal is branched and input into the SOAs arranged in parallel and amplifying different wavelength bands, thereby achieving wide wavelength characteristics for optical amplification despite the compact size. Furthermore, the outputs from the SOAs are monitored and the gains of the SOAs are controlled by the control unit, thereby stabilizing the optical output even when the input optical signal fluctuates and/or the optical amplifier such as the SOA degrades over time. Furthermore, the gains are variable and controllable while keeping wide wavelength characteristics for optical amplification.

According to the optical amplifier and the manufacturing method of the optical amplifier disclosed herein, wavelengths in a broad band can be amplified by a small optical amplifier of a simple configuration.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An optical amplifier comprising:
a plurality of semiconductor optical amplifiers (SOAs) provided on a semiconductor substrate and having different wavelength bands to be amplified;
a plurality of branching paths that branch an input optical signal and input the branched optical signals into the parallel SOAs, respectively; and
a plurality of combining paths that combine and output the optical signals after amplification by the SOAs.

2. The optical amplifier according to claim 1, wherein the SOAs are set such that an end of a wavelength band to be amplified of one SOA where the gain attenuates by a given value is overlapped with an end of another SOA having a different wavelength band to be amplified and thereby, broaden the amplified wavelength band of the combined optical signal.

3. The optical amplifier according to claim 2, wherein the SOAs set, within a given range and based on a tilt of center wavelengths according to a change in gains, variable gains and wavelength bands to be amplified that change according to a change in the gains.

4. The optical amplifier according to claim 1, wherein each of the branching paths and the combining paths is a path in the air formed by a lens, an optical fiber, or an optical waveguide formed on the semiconductor substrate.

5. The optical amplifier according to claim 1, further comprising:
a plurality of monitors that detect output levels of the SOAs, respectively; and
a control unit that performs a gain control to adjust a gain of a corresponding SOA based on a change in an output detected by any of the monitors and to keep the output level of the SOA constant.

6. The optical amplifier according to claim 1, wherein
optical path lengths of the branching paths provided upstream of the SOAs are the same, and
optical path lengths of the combining paths provided downstream of the SOAs are the same.

7. The optical amplifier according to claim 1, wherein
the combining paths are optical waveguides formed on the semiconductor substrate, and
the optical amplifier further comprising:
control electrodes having a given length and provided along the combining paths;
a monitor that detects outputs from the SOAs; and
a control unit that performs a phase control to adjust, based on a change in the outputs detected by the monitor, a voltage applied to a control electrode corresponding to a range of wavelengths for which the change is detected, and to keep the output from the SOA constant.

8. A manufacturing method of an optical amplifier, comprising:
forming branching paths that branch an input optical signals and combining paths that combine the branched optical signals on a semiconductor substrate, as optical waveguides by forming a multi-layered semiconductor thin film; and
forming SOAs by providing electrodes on the optical waveguides at portions located within given areas between the branching paths and the combining paths.

9. The manufacturing method according to claim 8, wherein the forming the SOAs includes
forming a plurality of SOAs having different wavelengths to be amplified on the semiconductor substrate, and
when one SOA is formed, areas for other SOAs are masked and after the SOA is formed by using source gas having a concentration corresponding to a given wavelength to be amplified, another SOA is formed by masking areas for other SOAs and using material gas having a concentration corresponding to a given wavelength to be amplified.

10. The manufacturing method according to claim 8, wherein the forming the SOAs includes
forming the SOAs on the semiconductor substrate to form an array.
